(19) United States
(12) Patent Application Publication
(10) Pub. No.: US 2014/0211435 A1
(43) Pub. Date: Jul. 31, 2014

(54) CONDUCTIVE MEMBER CONNECTION STRUCTURE, CONDUCTIVE MEMBER CONNECTION METHOD AND OPTICAL MODULE

(71) Applicant: Hitachi Metals, Ltd., Tokyo (JP)

(72) Inventors: Hiroki YASUDA, Mito (JP); Juhyun YU, Mito (JP); Kouki HIRANO, Hitachinaka (JP); Hiroshi KOMURO, Hitachi (JP); Osamu SEYA, Hitachi (JP)

(73) Assignee: Hitachi Metals, Ltd., Tokyo (JP)

(21) Appl. No.: 14/151,215

(22) Filed: Jan. 9, 2014

(30) Foreign Application Priority Data
Jan. 30, 2013 (JP) 2013-015429

(51) Int. Cl. H01R 13/02; H01R 43/26; H05K 1/18

(52) U.S. Cl. CPC H01R 13/02; H05K 1/181; H01R 43/26
USPC 361/760; 439/884; 29/879

(57) ABSTRACT

A conductive member connection structure includes a connection structure to electrically connect first and second conductive members that are positioned with a gap in between, a first metal member that is melted by heating and is welded to a connecting surface of the first conductive member and to a connecting surface of the second conductive member, and a second metal member that has a higher melting point than the first metal member and is covered with the first metal member without being melted by the heating. The second metal member is configured so as to prevent the first metal member from flowing out in a molten state thereof.

The present application is based on Japanese patent application No. 2013-015429 filed on Jan. 30, 2013, the entire contents of which are incorporated herein by reference.

### BACKGROUND OF THE INVENTION

1. Field of the Invention

The invention relates to a conductive member connection structure with conductive members electrically connected to each other, a connection method thereof and an optical module using the conductive member connection structure.

2. Description of the Related Art

JP-A-2009-054741 discloses a connection structure that a solder is used to connect electrodes on a pair of substrates arranged facing each other with a gap therebetween.

The connection structure disclosed in JP-A-2009-054741 is constructed such that a bump is provided on a surface of one of the electrodes while projecting toward the other electrode so as to allow the solder connection even if the distance between the electrodes increases due to warping etc. of the substrates. The bump can help narrow the gap to hold the solder disposed therein so as to have the sure solder electrical connection between the electrodes.

### SUMMARY OF THE INVENTION

The structure disclosed in JP-A-2009-054741 has the problem that the bump may cause a complicated manufacturing process and an increase in the manufacturing cost. In addition, according as the amount of solder needed to fill the gap between the electrodes increases, the molten solder may be flown out so as to form a solder bridge when the solder is used for connecting the plural adjacent electrodes formed at an end portion of the substrates.

It is an object of the invention to provide a conductive member connection structure that allows the sure connection between the conductive members while reducing the amount of a metal member to be molten during the connection therebetween, as well as a conductive member connection method and an optical module for achieving or deriving from the connection structure.

(1) According to one embodiment of the invention, a conductive member connection structure comprises:

a connection structure to electrically connect first and second conductive members that are positioned with a gap in between;

a first metal member that is melted by heating and is welded to a connecting surface of the first conductive member and to a connecting surface of the second conductive member; and

a second metal member that has a higher melting point than the first metal member and is covered with the first metal member without being melted by the heating,

wherein the second metal member is configured so as to prevent the first metal member from flowing out in a molten state thereof

(2) According to another embodiment of the invention, a conductive member connection method for electrically connecting first and second conductive members that are positioned with a gap in between, comprises:

arranging a connecting member so as to be in contact with at least one of the first and second conductive members, the connecting member comprising a first metal member and a second metal member that has a higher melting point than the first metal member and is covered with the first metal member; and

electrically connecting the first conductive member to the second conductive member by melting only the first metal member, between the first and second metal members, with heat and welding the molten first metal member to a connecting surface of the first conductive member and to a connecting surface of the second conductive member.

(3) According to another embodiment of the invention, an optical module comprises:

a circuit board comprising a first electrode;

a photoelectric conversion element mounted on the circuit board;

an optical coupling member for optically coupling an optical fiber to the photoelectric conversion element;

a plate-shaped supporting substrate that is arranged to sandwich the optical coupling member between itself and the circuit board and has a second electrode formed on a side surface;

a first metal member that is melted by heating and is welded to a connecting surface of the first conductive member and to a connecting surface of the second conductive member; and

a second metal member that has a higher melting point than the first metal member and is covered with the first metal member without being melted by the heating.

### EFFECTS OF THE INVENTION

According to one embodiment of the invention, a conductive member connection structure can be provided that allows the sure connection between the conductive members while reducing the amount of a metal member to be molten during the connection therebetween, as well as a conductive member connection method and an optical module for achieving or deriving from the connection structure.

### BRIEF DESCRIPTION OF THE DRAWINGS

Next, the present invention will be explained in more detail in conjunction with appended drawings, wherein:

FIG. 1 is a perspective view showing an optical module in an embodiment;

FIG. 2 is a cross sectional view taken along a line A-A of FIG. 1;

FIG. 3A is a perspective view showing a supporting substrate and FIG. 3B is a perspective view showing a bar-shaped member from which supporting substrate are diced out;

FIG. 4 is a side view showing an optical module 1 on the opposite side to the side surface with a frame body provided thereon;

FIG. 5 is a schematic view showing an example of a method of connecting a lower electrode to a lead electrode; and

FIG. 6 is a side view showing an optical module in Comparative Example of the embodiment on the opposite side to the side surface with a frame body provided thereon.

### DETAILED DESCRIPTION OF THE PREFERRED EMBODIMENTS

### Embodiment

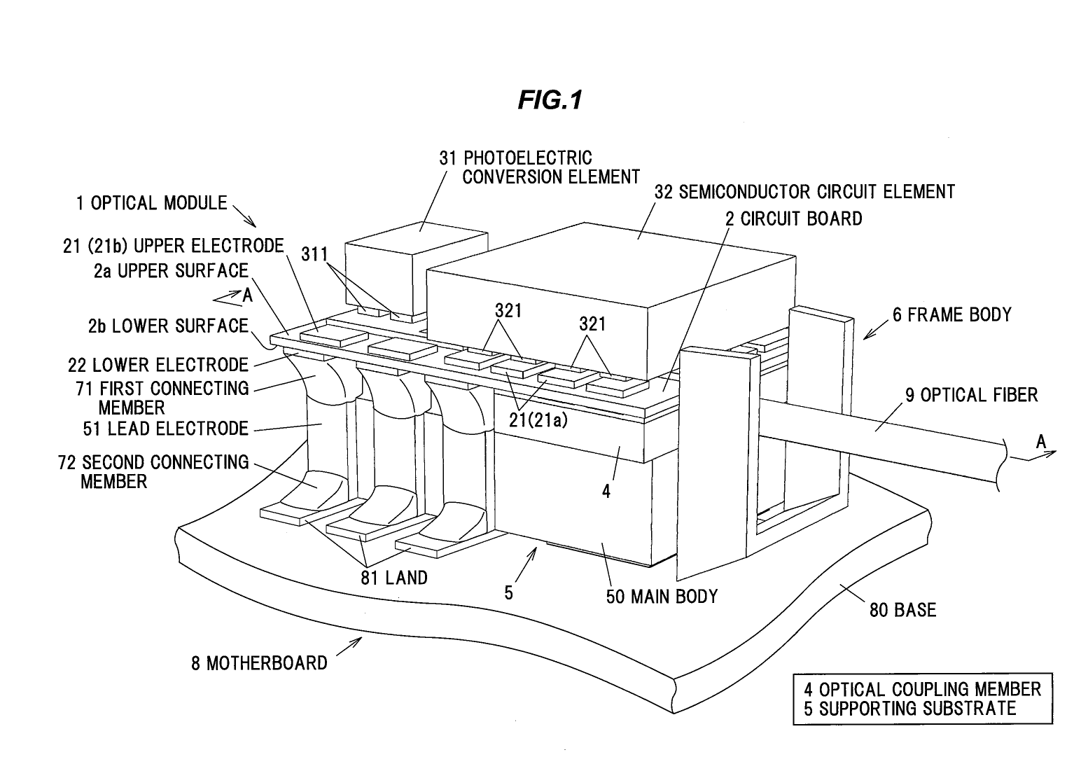

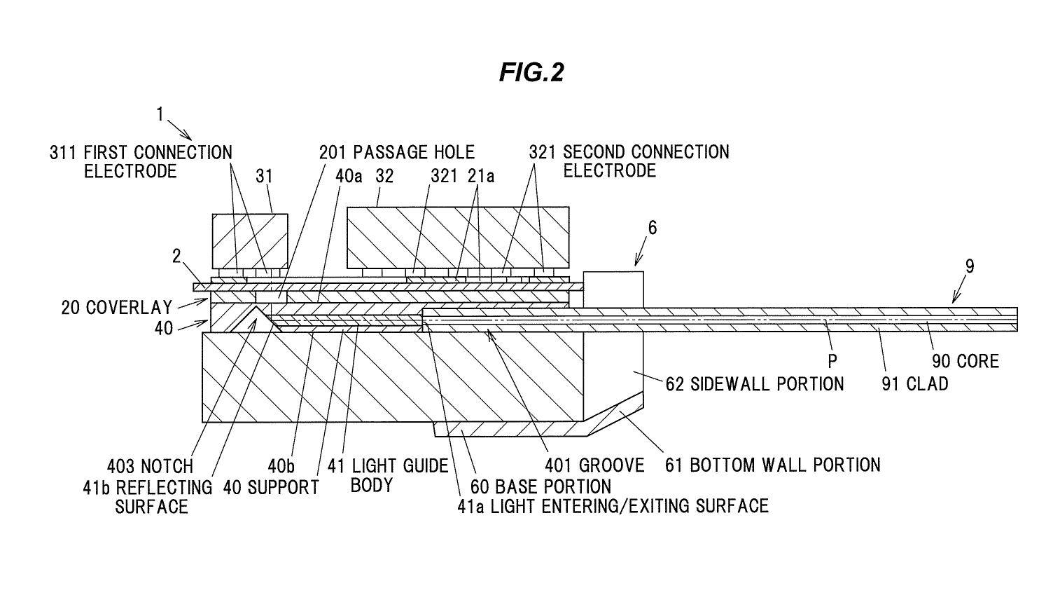

FIG. 1 is a perspective view showing an optical module in the embodiment. FIG. 2 is a cross sectional view showing the optical module 1 taken on line A-A along an axis of an optical fiber 9 mounted on the optical module 1.

Structure of Optical Module 1

The optical module 1 is used in a state of being mounted on a motherboard 8, as shown in FIG. 1. The motherboard 8 is, e.g., a glass epoxy substrate in which a wiring pattern including plural lands 81 is formed on a plate-shaped base 80 made of glass fiber impregnated with epoxy resin and then subjected to thermosetting treatment. Non-illustrated electronic components such as CPU (Central Processing Unit) or storage unit are mounted on the motherboard 8 and transmit or receive signals to/from another electronic circuit board or electronic device through optical communication in which the optical fiber 9 mounted on the optical module 1 is used as a transmission medium.

The optical module 1 is provided with a circuit board 2, a photoelectric conversion element 31 mounted on an upper surface 2a of the circuit board 2, an optical coupling member 4 holding the optical fiber 9 and also optically coupling the photoelectric conversion element 31 to the optical fiber 9, a semiconductor circuit element 32 mounted on the upper surface 2a of the circuit board 2 and electrically connected to the photoelectric conversion element 31, a plate-shaped supporting substrate 5 arranged to sandwich the optical coupling member 4 between itself and the circuit board 2, and a frame body 6.

On a side surface(s) of the supporting substrate 5, a lead electrode(s) 51 as a second conductive member extending in a thickness direction of the supporting substrate 5 (a direction perpendicular to the motherboard 8) is formed integrally with a main body 50. An end portion of the lead electrode 51 is connected by a first connecting member 71 to a lower electrode 22 as a first conductive member provided on a lower surface 2b of the circuit board 2. Another end portion of the lead electrode 51 is connected to the land 81 of the motherboard 8 by a second connecting member 72.

As shown in FIG. 2, a coverlay 20 formed of an insulating film is provided on the circuit board 2 on the optical coupling member 4 side. The coverlay 20 is a plate-shaped optically-transparent insulation and is formed of, e.g., PI (polyimide). A passage hole 201 providing a passage for light propagating through the optical fiber 9 is formed on the coverlay 20. In addition, the coverlay 20 is formed in size and shape to cover the optical coupling member 4. Between the coverlay 20 and the circuit board 2 and between the coverlay 20 and the optical coupling member 4 are respectively fixed to each other by an adhesive, etc.

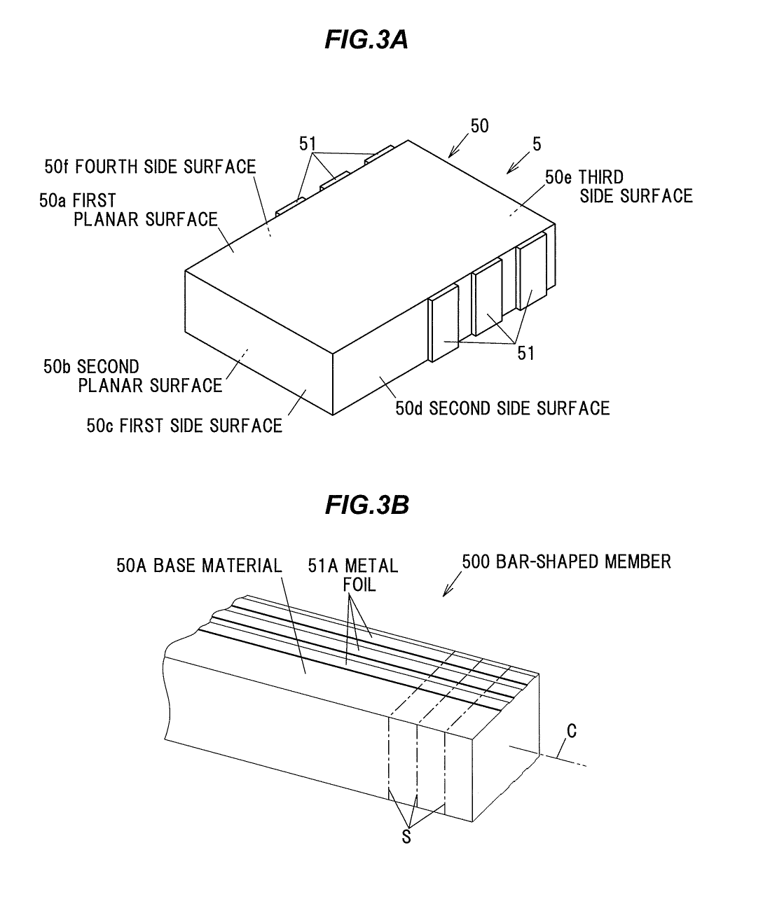

The frame body 6 formed by bending a metal such as stainless steel is fixed to the supporting substrate 5. The frame body 6 is formed to surround, from three directions, around the optical fiber 9 connected to the optical module 1. The frame body 6 has integrally a plate-shaped base portion 60, a bottom wall portion 61 adjacently connected to the base portion 60, and a pair of sidewall portions 62 provided in a standing manner at both edges of the bottom wall portion 61. The base portion 60 is fixed to a below-described second planar surface 50b of the supporting substrate 5 (see FIG. 3A) by adhesive bonding. The optical fiber 9 is fixed to the frame body 6 by an adhesive, etc., which is filled in a space between the pair of sidewall portions 62.

The optical module 1, is, e.g., 3.0 mm in whole length along an extending direction of the optical fiber 9 and is, e.g., 2.0 mm in size in a width direction orthogonal to such a direction. In addition, the size of the optical module 1 in a height direction (a direction perpendicular to the motherboard 8) is, e.g., 0.8 mm.

The photoelectric conversion element 31 is an element which converts an electric signal into an optical signal or an optical signal into an electric signal. Examples of the former which is a light-emitting element include a laser diode and a VCSEL (Vertical Cavity Surface Emitting Laser), etc. Meanwhile, examples of the latter which is a light-receiving element include a photodiode. The photoelectric conversion element 31 is configured to emit light toward the optical fiber 9 or to receive light from the optical fiber 9.

When the photoelectric conversion element 31 is an element which converts an electric signal into an optical signal, the semiconductor circuit element 32 is a driver IC which drives the photoelectric conversion element 31 based on an electric signal input from the electronic circuit board. On the other hand, when the photoelectric conversion element 31 is an element which converts the received optical signal into an electric signal, the semiconductor circuit element 32 is a receiver IC which amplifies an electric signal input from the photoelectric conversion element 31 and outputs the amplified electric signal to the electronic circuit.

Structure of Circuit Board 2

The circuit board 2 is a flexible substrate in which plural electrodes made of a conductive metal foil are formed on a front surface of the base made of flexible and optically-transparent film-shaped insulation. Plural upper electrodes 21 are provided on the upper surface 2a on which the photoelectric conversion element 31 and the semiconductor circuit element 32 are also mounted. Plural lower electrodes 22 as second conductive members are provided on the lower surface 2b which is located on the opposite side to the upper surface 2a.

The lead electrodes 51 of the supporting substrate 5 are respectively connected to the plural lower electrodes 22 via the first connecting members 71. The optical module 1 in the present embodiment has six lower electrodes 22 and six lead electrodes 51. In addition, the lower electrodes 22 are provided at an edge of the lower surface 2b.

The plural upper electrodes 21 on the upper surface 2a are classified into connecting electrodes 21a and test electrodes 21b according to the function thereof. As shown in FIG. 2, the connecting electrode 21a is an electrode which is connected by solder to a first connection electrode 311 of the photoelectric conversion element 31 or a second connection electrode 321 of the semiconductor circuit element 32.

The test electrode 21b is an electrode for a performance test conducted on the optical module 1 alone which is not mounted on the motherboard 8. A performance test probe comes into contact with the test electrode 21b, and power supply and input/output of test signals are carried out through the probe. In the present embodiment, plural (four) test electrodes 21b are arranged around the photoelectric conversion element 31 which has a smaller mounting area than the semiconductor circuit element 32.

Structure of Optical Coupling Member 4

The optical coupling member 4 is composed of a support 40 for holding the optical fiber 9 and a light guide body 41 for guiding propagation light which propagates through the optical fiber 9. Both the support 40 and the light guide body 41 are optically transparent to wavelength of the propagation light which propagates through the optical fiber 9, and the guide body 41 has a higher refractive index than that of the support 40. The support 40 is formed of, e.g., PI (polyimide) and the guide body 41 is formed of, e.g., acrylic, epoxy, PI or polysiloxane, etc.

The support 40 is plate-shaped and has a flat front surface 40a facing the coverlay 20 and a back surface 40b parallel to the front surface 40a and facing the supporting substrate 5. On the back surface 40b, the support 40 has a groove 401 which is open on the supporting substrate 5 side to house a tip of the optical fiber 9. The groove 401 extends along a direction of aligning the semiconductor circuit element 32 and the photoelectric conversion element 31 and is recessed on the support 40 from the back surface 40b toward the front surface 40a in a thickness direction of the support 40. The light guide body 41 is formed to communicate with the groove 401 so that the central axis thereof is parallel to the extending direction of the groove 401.

A notch 403 is formed on the back surface 40b of the support 40. The notch 403 is formed on the support 40 from one surface toward the other surface such that the extending direction thereof is orthogonal to the central axis of the light guide body 41. In addition, the notch 403 has a triangular shape in a side view and one of side surfaces thereof terminates the light guide body 41. The angle formed by the notch 403 and the back surface 40b is, e.g., 45°. Note that, a resin may be filled in the notch 403.

In the light guide body 41, an end on the groove 401 side is a light entering/exiting surface 41a and an inclined surface terminated by the side surface of the notch 403 is a reflecting surface 41b. The light entering/exiting surface 41a is provided at a position facing a core 90, surrounded by a clad 91, of the optical fiber 9 held in the groove 401. The reflecting surface 41b reflects light emitted from the photoelectric conversion element 31 toward the light entering/exiting surface 41a or reflects light incident from the light entering/exiting surface 41a toward the photoelectric conversion element 31.

The tip of the optical fiber 9 housed in the groove 401 of the support 40 is sandwiched and held between the support 40 (a bottom surface of the groove 401) and the supporting substrate 5, as shown in FIG. 2.

Structure of Supporting Substrate 5

FIG. 3A is a perspective view showing the supporting substrate 5 and FIG. 3B is a perspective view showing a bar-shaped member 500 from which the supporting substrates 5 are diced out.

The supporting substrate 5 has integrally the rectangular parallelepiped main body 50 formed an insulating resin and plural lead electrodes 51 (six in the present embodiment) formed on side surfaces of the main body 50. The main body 50 has a first planar surface 50a facing the optical coupling member 4, the second planar surface 50b facing the motherboard 8, and first to fourth side surfaces 50c, 50d, 50e and 50f. In the present embodiment, among the first to fourth side surfaces 50c to 50f of the main body 50, the second side surface 50d and the fourth side surface 50f, which are parallel to the central axis of the light guide body 41 and opposite to each other, each have three lead electrodes 51.

The lead electrodes 51 are formed to extend along a thickness direction of the supporting substrate 5 (a direction perpendicular to the first planar surface 50a and the second planar surface 50b) from an edge of the first planar surface 50a facing the back surface 40b of the optical coupling member 4 to an edge of the second planar surface 50b located on the opposite side.

In the present embodiment, the main body 50 is formed of a material containing glass. In more detail, the main body 50 is formed of glass epoxy which is glass fiber impregnated with epoxy resin and then subjected to thermosetting treatment, and a material of the main body 50 in the present embodiment is so-called FR4 (Flame Retardant Type 4). Meanwhile, the lead electrode 51 consists mainly of copper with gold plating on a surface thereof.

The main body 50 has a thickness of, e.g., not more than 0.5 mm and is optically transparent such that the tip of the optical fiber 9 housed in the groove 401 of the optical coupling member 4 is visible through the second planar surface 50b located on the opposite side to the first planar surface 50a.

As shown in FIG. 3B, the supporting substrate 5 is formed by dicing the bar-shaped member 500. The following is the more detailed description. The bar-shaped member 500 has integrally a base material 50A to be the main body 50 of the supporting substrate 5 and linear metal foils 51A to be the lead electrodes 51 of the supporting substrate 5 which are formed on side surfaces of the base material 50A along a central axis C of the base material 50A.

In the bar-shaped member 500, copper sheets are attached and adhered so as to cover side surfaces of the pre-polished base material 50A, are etched into the shape corresponding to the linear metal foils 51A and are plated with nickel and gold, thereby forming the metal foils 51A. Alternatively, the metal foils 51A may be formed by, e.g., vapor deposition. In addition, nickel plating and flux may be applied in place of gold plating.

The bar-shaped base material 50A, together with the metal foils 51A, is diced by section planes orthogonal to the central axis C, thereby forming the supporting substrates 5. In FIG. 3B, section lines S of the bar-shaped member 500 are indicated by dashed-dotted lines. That is, a cut plane of the bar-shaped member 500 is the first planar surface 50a or the second planar surface 50b of the supporting substrate 5.

Connection Structure of Lower Electrode 22 and Lead Electrode 51

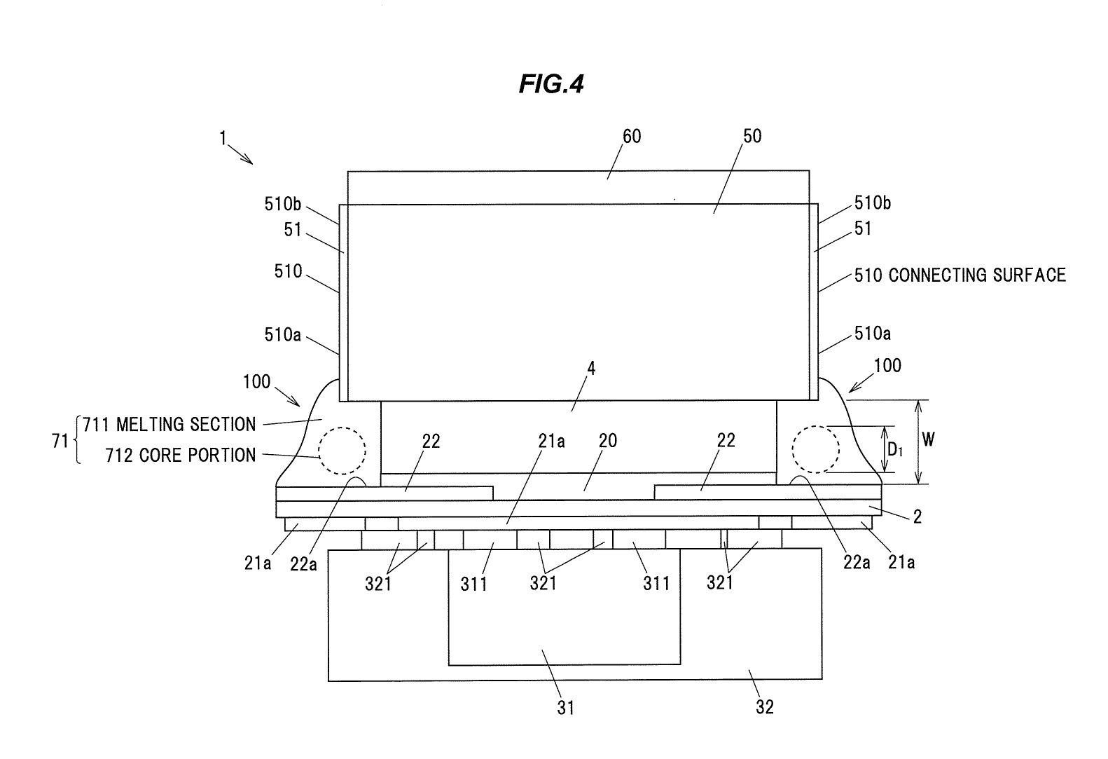

FIG. 4 is a side view showing the optical module 1 on the opposite side to the side surface with the frame body 6 provided thereon. It should be noted that, in FIG. 4, the optical module 1 is shown upside down in a direction perpendicular to the motherboard 8, based on the state during manufacture described later. In FIG. 4, core portions 712 are indicated by a dashed line.

The six lower electrodes 22 mounted on the lower surface 2b of the circuit board 2 and the six lead electrodes 51 provided on the second side surface 50d and the fourth side surface 50f of the supporting substrate 5 are positioned with gaps 100 in between. A connecting surface 510 of the lead electrode 51 to which the first connecting member 71 is welded extends in a direction crossing a surface 22a as a connecting surface of the lower electrode 22 to which the first connecting member 71 is also welded. In the present embodiment, the connecting surface 510 of the lead electrode 51 extends in a direction orthogonal to the surface 22a of the lower electrode 22. Two of the lower electrodes 22 and two of the six lead electrodes 51 are shown in FIG. 4.

In the present embodiment, a width W (in a direction perpendicular to the circuit board 2) of the gap 100 between the lower electrode 22 and the lead electrode 51 is 50 μm to 200 μm. The conductive first connecting member 71 electrically connecting the lower electrode 22 to the lead electrode 51 is present in the gap 100.

The first connecting member 71 is provided with a melting section 711 and the core portion 712. The melting section 711 is a first metal member which is melted by heat and is welded to the surface 22a of the lower electrode 22 as well as to an end portion 510a of the connecting surface 510 of the lead electrode 51. The core portion 712 is a second metal member which has a higher melting point than the melting section 711 and is covered with the melting section 711 without being melted by heat.

The first metal member as the melting section 711 is formed of solder. The solder is lead-free solder made of, e.g., a SnAgCu-based alloy containing tin (Sn), silver (Ag) and copper (Cu), a SnZnBi-based alloy containing tin (Sn), zinc (Zn) and bismuth (Bi) or an alloy containing tin (Sn), silver (Ag), indium (In) and bismuth (Bi), etc. In the present embodiment, lead-free solder made of a SnAgCu-based alloy having a melting point of up to 220° C. is used.

The second metal member as the core portion 712 consists mainly of copper (Cu) of which melting point is 1084.62° C. Therefore, when the first connecting member 71 is heated at a temperature of, e.g., from 220° C. to 1000° C., only the melting section 711 is melted and the core portion 712 remains as a solid without being melted and is covered with the molten melting section 711. In other words, flow of the molten melting section 711 is suppressed by presence of the core portion 712.

The core portion 712 has a spherical shape and at least a portion thereof is present in the gap 100. When the diameter of the core portion 712 is defined as D₁ and the width of the gap 100 is defined as W, D₁ should be not less than W/2 and not more than 2W (W/2≦D₁≦2W). A desirable range of the diameter D₁ of the core portion 712 is not less than W/2 and not more than W (W/2≦D₁≦W).

In addition, the first connecting member 71 in the present embodiment has also a spherical shape and a desirable range of a diameter D₂ of the first connecting member 71 is not less than 1.1 times and not more than twice the diameter D₁ (1.1×D₁≦D₁≦2×D₁).

Method of Connecting Lower Electrode 22 to Lead Electrode 51

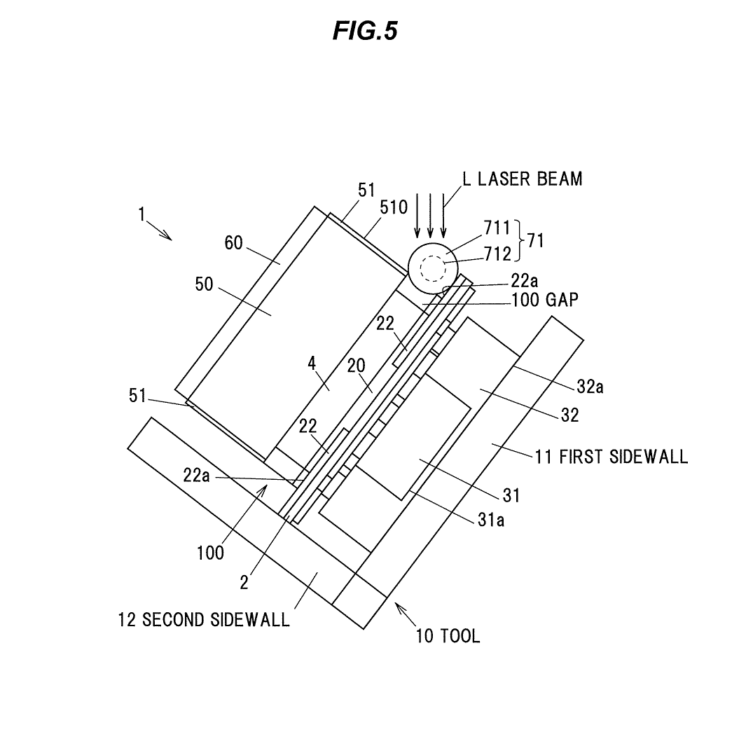

Next, the method of connecting the lower electrode 22 to the lead electrode 51 will be described. FIG. 5 is a schematic view showing an example of a method of connecting the lower electrode 22 to the lead electrode 51.

The connection process for electrically connecting the lower electrode 22 and the lead electrode 51 which are positioned with the gap 100 in between includes an arrangement step in which the first connecting member 71 composed of the melting section 711 and the core portion 712 having a higher melting point than the melting section 711 and covered with the melting section 711 is arranged so as to be in constant with the lower electrode 22 and the lead electrode 51, and a connecting step of electrically connecting the lower electrode 22 to the lead electrode 51 in which, of the melting section 711 and the core portion 712, only the melting section 711 is melted by heating the first connecting member 71 and is welded to the surface 22a of the lower electrode 22 as well as to the end portion 510a of the connecting surface 510 of the lead electrode 51. Each step will be described in more detail below. It should be noted that the work procedure in each step is shown as an example and it is not limited thereto.

Arrangement Step

In the arrangement step, the optical module 1 not yet having the first connecting member 71 inserted thereinto is placed on a tool 10 having a first sidewall 11 and a second sidewall 12 which are orthogonal to each other. In more detail, the optical module 1 is placed so that an upper surface 31a of the photoelectric conversion element 31 and an upper surface 32a of the semiconductor circuit element 32 face the first sidewall 11. The optical module 1 placed on a tool 10 is inclined with respect to the horizontal direction so that the surface 22a of the lower electrode 22 faces vertically upward.

Next, the first connecting member 71 is placed so that the outermost surface thereof is in contact with the lower electrode 22 as well as the lead electrode 51. Alternatively, the outermost surface of the first connecting member 71 may be in contact with only the surface 22a of the lower electrode 22. In other words, the entire first connecting member 71 may be placed inside the gap 100.

In the present embodiment, a flux is applied to the outermost surface of the first connecting member 71. The flux is made of, e.g., a saturated aqueous solution of zinc chloride (ZnCl) or a pine resin, etc., and is melted at about 90° C. Therefore, the flux is melted before melting of the melting section 711 which is formed of solder, and this improves wetting (flow) of the solder. Alternatively, the flux may be applied to the surface 22a of the lower electrode 22 and the lead electrode 51 instead of applying to the outermost surface of the first connecting member 71. In other words, the first connecting member 71 is arranged between the lower electrode 22 and the lead electrode 51 with the interposition of the flux.

Connecting Step

In the connecting step, of the second metal member as the core portion 712 and the first metal member as the melting section 711, only the first metal member (the melting section 711) is melted by irradiation of a laser beam L onto the first connecting member 71. Although irradiation of the laser beam L is used to heat the first connecting member 71 in the present embodiment, the first connecting member 71 may be heated by, e.g., heated air, etc. The molten first metal member (the melting section 711) is welded to the surface 22a of the lower electrode 22 as well as to the end portion 510a of the connecting surface 510 of the lead electrode 51, thereby electrically connecting the lower electrode 22 to the lead electrode 51.

In more detail, a portion of the molten first metal member (the melting section 711) spreads and is welded to the surface 22a of the lower electrode 22 while another portion spreads and is welded to the end portion 510a of the connecting surface 510 of the lead electrode 51.

Operation of Optical Module 1

Next, operation of the optical module 1 will be described in reference to FIG. 2.

The explanation here focuses on the case where the photoelectric conversion element 31 is a VCSEL (Vertical Cavity Surface Emitting Laser) and the semiconductor circuit element 32 is a driver IC for driving the photoelectric conversion element 31.

The optical module 1 is operated by receiving operating power supply from the motherboard 8. The operating power is input to the photoelectric conversion element 31 and the semiconductor circuit element 32 via the lead electrode 51 of the supporting substrate 5 and the circuit board 2. Meanwhile, signals to be transmitted using the optical fiber 9 as a transmission medium are input to the semiconductor circuit element 32 from the motherboard 8 via the lead electrode 51 of the supporting substrate 5 and the circuit board 2. The semiconductor circuit element 32 drives the photoelectric conversion element 31 based on the input signal.

The photoelectric conversion element 31 emits laser light in a direction perpendicular to the upper surface 2a toward the upper surface 2a of the circuit board 2 from a light emitting/receiving portion formed on a surface facing the circuit board 2. In FIG. 2, an optical path P of the laser beam is indicated by a two-dot chain line.

The laser beam transmits through the base of the circuit board 2 and the coverlay 20 and is then incident on the optical coupling member 4. The laser beam incident on the optical coupling member 4 is reflected by the reflecting surface 41b, is guided by the light guide body 41 and is incident on the core 90 of the optical fiber 9 from the light entering/exiting surface 41a.

When the photoelectric conversion element 31 is, e.g., a photodiode and the semiconductor circuit element 32 is a receiver IC, the light-traveling direction is reversed and the photoelectric conversion element 31 converts the received optical signal into an electric signal and outputs the electric signal to the semiconductor circuit element 32. The semiconductor circuit element 32 then amplifies the electric signal and outputs the amplified electric signal to the motherboard 8 via the circuit board 2 and the lead electrode 51 of the supporting substrate 5.

Comparative Example

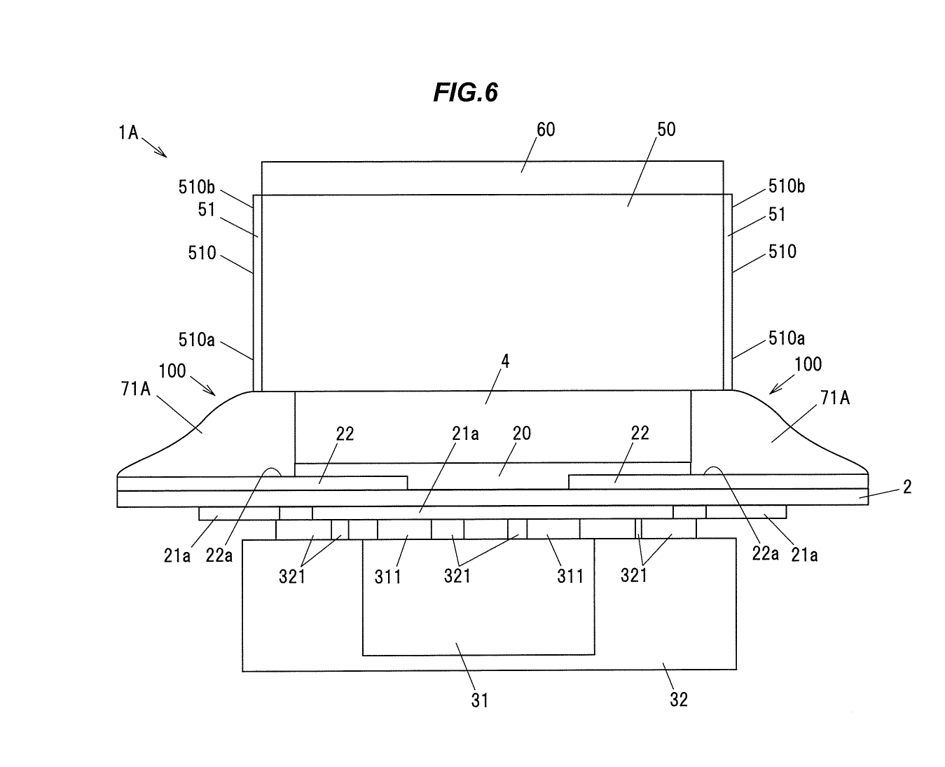

FIG. 6 is a side view showing an optical module 1A in Comparative Example of the embodiment on the opposite side to the side surface with the frame body 6 provided thereon.

In the optical module 1A of Comparative Example, the structure of a first connecting member 71A is different from the structure of the first connecting member 71 in the embodiment. In FIG. 6, portions having the same functions as those described for the optical module 1 are denoted by the same reference numerals and the overlapping explanation thereof will be omitted.

As shown in FIG. 6, the first connecting member 71A is composed of only the first metal member formed of solder. In this case, the first connecting member 71A melted by heat spreads on the surface 22a of the lower electrode 22 but is less likely to spread on the connecting surface 510 of the lead electrode 51 which is arranged with the gap 100. Therefore, in order to fill the gap 100 present between the lower electrode 22 and the lead electrode 51, the required amount of the solder constituting the first connecting member 71A is more than the amount of the solder (the melting section 711) in the embodiment.

Meanwhile, an another end portion 510b of the connecting surface 510 of the lead electrode 51 and the land 81 provided on the motherboard 8 are connected by the second connecting member 72 formed of solder, and the optical module 1A is thereby mounted on the motherboard 8 (see FIG. 1). On this occasion, heat for heating the second connecting member 72 may be transferred to the end portion 510a of the connecting surface 510 of the lead electrode 51, causing the first connecting member 71A to be melted. The molten first connecting member 71A may flow down toward the motherboard 8 along the connecting surface 510 of the lead electrode 51.

Functions and Effects of the Embodiment

The following functions and effects are obtained in the embodiment.

(1) Since the first connecting member 71 is provided with the melting section 711 melted by heat and welded to the surface 22a of the lower electrode 22 as well as to the end portion 510a of the connecting surface 510 of the lead electrode 51 and the core portion 712 having a higher melting point than the first metal member as the melting section 711 and covered with the melting section 711 without being melted by heat, it is possible to suppress the flow of the molten first metal member (the melting section 711) by the core portion 712. As a result, the melting section 711 is welded to not only the surface 22a of the lower electrode 22 but also to the end portion 510a of the connecting surface 510 of the lead electrode 51 which is arranged with the gap 100. This allows reliable electrical connection between the lower electrode 22 and the lead electrode 51 while reducing the amount of the solder constituting the melting section 711.

(2) The first connecting member 71 is provided with the core portion 712. Therefore, even if the melting section 711 of the first connecting member 71 is re-melted by the heat for heating the second connecting member 72 at the time of mounting the optical module 1 on the motherboard 8, it is possible to prevent the molten melting section 711 from flowing down toward the motherboard 8 along the connecting surface 510 of the lead electrode 51.

(3) Since at least a portion of the core portion 712 is present in the gap 100, the molten first metal member (the melting section 711) flows around in the gap 100 and is then welded. This makes the electrical connection between the lower electrode 22 and the lead electrode 51 more reliable.

(4) The core portion 712 has a spherical shape and thus easily enters into the gap 100 when the melting section 711 is melted.

(5) In the arrangement step in the method of connecting the lower electrode 22 to the lead electrode 51, the first connecting member 71 is arranged between the lower electrode 22 and the lead electrode 51 with the interposition of the flux. Therefore, movement (rolling motion) of the first connecting member 71 after being arranged can be suppressed by viscosity of the flux.

Summary of the Embodiment

Technical ideas understood from the embodiment will be described below citing the reference numerals, etc., used for the embodiment. However, each reference numeral, etc., described below is not intended to limit the constituent elements in the claims to the members, etc., specifically described in the embodiment.

[1] A conductive member connection structure for electrically connecting a first conductive member (lower electrode 22) to a second conductive member (lead electrode 51) that are positioned with a gap (100) in between, comprising: a first metal member (melting section 711) that is melted by heating and is welded to a connecting surface (surface 22a) of the first conductive member (lower electrode 22) and to a connecting surface (510) of the second conductive member (lead electrode 51); and a second metal member (core portion 712) that has a higher melting point than the first metal member (melting section 711) and is covered with the first metal member (melting section 711) without being melted by the heating, wherein flow of the first metal member (melting section 711) in a molten state is suppressed by the second metal member (core portion 712).

[2] The structure described in the [1], wherein at least a portion of the second metal member (core portion 712) is present in the gap (100).

[3] The structure described in the [1] or [2], wherein the second metal member (core portion 712) has a spherical shape.

[4] The structure described in the [3], wherein a diameter (D₁) of the second metal member (core portion 712) is not less than half and not more than double the size of the gap (100).

[5] The structure described in the [1], wherein the connecting surface (510) of the second conductive member (lead electrode 51) extends in a direction crossing the connecting surface (surface 22a) of the first conductive member (lower electrode 22).

[6] A conductive member connection method for electrically connecting a first conductive member (lower electrode 22) to a second conductive member (lead electrode 51) that are positioned with a gap (100) in between, comprising: arranging a connecting member (first connecting member 71) so as to be in contact with the first conductive member (lower electrode 22) and the second conductive member (lead electrode 51), the connecting member (first connecting member 71) comprising a first metal member (melting section 711) and a second metal member (core portion 712) that has a higher melting point than the first metal member (melting section 711) and is covered with the first metal member (melting section 711); and electrically connecting the first conductive member (lower electrode 22) to the second conductive member (lead electrode 51) by melting only the first metal member (melting section 711), between the first and second metal members (melting section 711 and core portion 712), with heat and welding the molten first metal member (melting section 711) to a connecting surface (surface 22a) of the first conductive member (lower electrode 22) and to a connecting surface (510) of the second conductive member (lead electrode 51).

[7] The method described in the [6], wherein the arranging is to arrange the connecting member (first connecting member 71) between the first conductive member (lower electrode 22) and the second conductive member (lead electrode 51) with the interposition of a flux.

[8] An optical module (1), comprising: a circuit board (2) comprising a first electrode(s) (lower electrode 22); a photoelectric conversion element (31) mounted on the circuit board (2); an optical coupling member (4) for optically coupling an optical fiber (9) to the photoelectric conversion element (31); a plate-shaped supporting substrate (5) that is arranged to sandwich the optical coupling member (4) between itself and the circuit board (2) and has a second electrode(s) (lead electrode 51) formed on a side surface(s); a first metal member (melting section 711) that is melted by heating and is welded to a connecting surface (surface 22a) of the first conductive member (lower electrode 22) and a connecting surface (510) of the second conductive member (lead electrode 51); and a second metal member (core portion 712) that has a higher melting point than the first metal member (melting section 711) and is covered with the first metal member (melting section 711) without being melted by the heating.

Although the embodiment of the invention have been described, the invention according to claims is not to be limited to the above-mentioned embodiment. Further, please note that all combinations of the features described in the embodiment are not necessary to solve the problem of the invention.

Although the core portion 712 consists mainly of copper (Cu) in the embodiment, it is not limited thereto. The core portion 712 may be formed of a conductive metal, e.g., iron (Fe), etc. Alternatively, an alloy of copper (Cu) plated with nickel (Ni), etc., may be used.

In addition, although the core portion 712 has a spherical shape in the embodiment, it is not limited thereto. The shape of the core portion 712 is not specifically limited. However, the spherical shape is the most desirable.

In addition, although one optical fiber 9 is mounted on the optical module 1 in the embodiment, it is not limited thereto. The optical module 1 may be configured so that plural optical fibers 9 are mounted thereon.

In addition, although one each of the photoelectric conversion element 31 and the semiconductor circuit element 32 are mounted on the circuit board 2 in the embodiment, it is not limited thereto. Plural photoelectric conversion elements 31 and plural semiconductor circuit elements 32 may be mounted.

In addition, materials of each member constituting the optical module 1 are not limited to those described in the embodiment.

What is claimed is:

1. A conductive member connection structure, comprising:
a connection structure to electrically connect first and second conductive members that are positioned with a gap in between;
a first metal member that is melted by heating and is welded to a connecting surface of the first conductive member and to a connecting surface of the second conductive member; and
a second metal member that has a higher melting point than the first metal member and is covered with the first metal member without being melted by the heating,
wherein the second metal member is configured so as to prevent the first metal member from flowing out in a molten state thereof.

2. The structure according to claim 1, wherein at least a portion of the second metal member is present in the gap.

3. The structure according to claim 1, wherein the second metal member has a spherical shape.

4. The structure according to claim 3, wherein a diameter of the second metal member is not less than half and not more than double a width of the gap.

5. The structure according to claim 1, wherein the connecting surface of the second conductive member extends in a direction intersecting with the connecting surface of the first conductive member.

6. A conductive member connection method for electrically connecting first and second conductive members that are positioned with a gap in between, comprising:
arranging a connecting member so as to be in contact with at least one of the first and second conductive members, the connecting member comprising a first metal member and a second metal member that has a higher melting point than the first metal member and is covered with the first metal member; and
electrically connecting the first conductive member to the second conductive member by melting only the first metal member, between the first and second metal members, with heat and welding the molten first metal member to a connecting surface of the first conductive member and to a connecting surface of the second conductive member.

7. The method according to claim 6, wherein the arranging is to arrange the connecting member between the first and second conductive members with the interposition of a flux.

8. An optical module, comprising:
a circuit board comprising a first electrode;
a photoelectric conversion element mounted on the circuit board;
an optical coupling member for optically coupling an optical fiber to the photoelectric conversion element;
a plate-shaped supporting substrate that is arranged to sandwich the optical coupling member between itself and the circuit board and has a second electrode formed on a side surface;
a first metal member that is melted by heating and is welded to a connecting surface of the first conductive member and to a connecting surface of the second conductive member; and
a second metal member that has a higher melting point than the first metal member and is covered with the first metal member without being melted by the heating.
